(19) United States
(12) Patent Application Publication
(10) Pub. No.: US 2026/0173364 A1
(43) Pub. Date: Jun. 18, 2026

(54) SEMICONDUCTOR DEVICE AND METHOD FOR FABRICATING THE SAME

(71) Applicant: SK hynix Inc., Gyeonggi-do (KR)

(72) Inventor: Young Gwang YOON, Gyeonggi-do (KR)

(21) Appl. No.: 19/375,217

(22) Filed: Oct. 31, 2025

(30) Foreign Application Priority Data
Dec. 13, 2024 (KR) 10-2024-0185605

(51) Int. Cl. H10B 12/00; H10D 30/01; H10D 62/832; H10D 64/66; H10D 64/68

(52) U.S. Cl. CPC H10B 12/50; H10D 62/832; H10D 64/667; H10D 64/669; H10D 64/681; H10D 64/691; H10D 64/693; H10D 30/027

(57) ABSTRACT

Disclosed is a semiconductor device including a metal gate electrode optimized for a peripheral region. The semiconductor device includes a substrate including a first NMOS region and a second NMOS region whose line width is different from a line width of the first NMOS region; a first conductive pattern including a stacked structure of a first gate dielectric layer and a first metal electrode over the substrate of the first NMOS region, and including a first high-k layer interposed at an interface between the first gate dielectric layer and the first metal electrode and containing a dipole-inducing chemical species; and a second conductive pattern including a stacked structure of a second gate dielectric layer and a second metal electrode over the substrate of the second NMOS region, and including a second high-k layer interposed at an interface between the second gate dielectric layer and the second metal electrode.

### CROSS-REFERENCE TO RELATED APPLICATIONS

The present application claims priority under 35 U.S. C 119(a) to Korean Patent Application No. 10-2024-0185605, filed on Dec. 13, 2024, which is incorporated herein by reference in its entirety.

### BACKGROUND

### 1. Field

Embodiments of the present disclosure relate to a semiconductor device, and more particularly, to a semiconductor device including a gate structure optimized for a peripheral area, and a method for fabricating the semiconductor device.

### 2. Description of the Related Art

As semiconductor devices achieve higher levels of integration, a significant challenge emerges concerning the reliability of gate dielectric layers. These layers are increasingly prone to breakdown, even under relatively low voltages, which can negatively impact the overall functionality and durability of the device. Therefore, it would be highly advantageous to develop a gate structure that may improve the performance of the device while at the same time preventing the gate dielectric layer from being broken down.

### SUMMARY

The embodiments of the present disclosure provide improved structures that not only enhance the performance metrics of the semiconductor devices but also ensure the integrity and stability of the gate dielectric layers.

Embodiments of the present disclosure are directed to a semiconductor device including a metal gate electrode which is optimized for a peripheral area.

In accordance with an embodiment of the present disclosure, a semiconductor device includes a substrate including a first NMOS region and a second NMOS region whose line width is different from a line width of the first NMOS region; a first conductive pattern including a stacked structure of a first gate dielectric layer and a first metal electrode in an upper portion of the substrate of the first NMOS region, and including a first high-k layer interposed at an interface between the first gate dielectric layer and the first metal electrode and containing a dipole-inducing chemical species; and a second conductive pattern including a stacked structure of a second gate dielectric layer and a second metal electrode in the upper portion of the substrate of the second NMOS region, and including a second high-k layer interposed at an interface between the second gate dielectric layer and the second metal electrode.

In accordance with another embodiment of the present disclosure, a semiconductor device includes a substrate including a first NMOS region, a second NMOS region whose line width is different from a line width of the first NMOS region, a first PMOS region, and a second PMOS region whose line width is different from a line width of the first PMOS region; a first conductive pattern including a stacked structure of a first gate dielectric layer and a first metal electrode in the upper portion of the substrate of the first NMOS region, and including a first high-k layer interposed at an interface between the first gate dielectric layer and the first metal electrode and containing a first dipole-inducing chemical species; a second conductive pattern including a stacked structure of a second gate dielectric layer and a second metal electrode in the upper portion of the substrate of the second NMOS region, and including a second high-k layer interposed at an interface between the second gate dielectric layer and the second metal electrode; a third conductive pattern including a stacked structure of a third gate dielectric layer and a third metal electrode in the upper portion of the substrate of the first PMOS region, and including a third high-k layer interposed at an interface between the third gate dielectric layer and the third metal electrode and containing a second dipole-inducing chemical species; and a fourth conductive pattern including a stacked structure of a fourth gate dielectric layer and a fourth metal electrode in the upper portion of the substrate of the second PMOS region, and including a fourth high-k layer interposed at an interface between the fourth gate dielectric layer and the fourth metal electrode and containing the second dipole-inducing chemical species.

In accordance with another embodiment of the present disclosure, a method for fabricating a semiconductor device includes preparing a substrate including a first NMOS region, a second NMOS region whose line width is different from a line width of the first NMOS region, a first PMOS region, and a second PMOS region whose line width is different from a line width of the first PMOS region; forming a P-channel layer in an upper portion of the substrate of the first PMOS region; sequentially forming a gate dielectric layer and a high-k layer in the upper portion of the substrate of the first NMOS region, the second NMOS region, and the second PMOS region and over the P-channel layer of the first PMOS region; forming a metal stack over the high-k layer of the first PMOS region and the second PMOS region; forming a dielectric capping layer including a first dipole-inducing chemical species over the high-k layer of the first NMOS region; and diffusing the first dipole-inducing chemical species in the dielectric capping layer into the interface between the high-k layer of the first NMOS region and the gate dielectric layer by performing an annealing process.

### BRIEF DESCRIPTION OF THE DRAWINGS

FIG. 1 is a cross-sectional view illustrating a semiconductor device in accordance with an embodiment of the present disclosure.

FIGS. 2A to 2I are process cross-sectional views illustrating a method for fabricating a semiconductor device in accordance with an embodiment of the present disclosure.

FIG. 3 is a cross-sectional view illustrating a semiconductor device in accordance with another embodiment of the present disclosure.

FIGS. 4A to 4I are process cross-sectional views illustrating a method for fabricating a semiconductor device in accordance with another embodiment of the present disclosure.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

A semiconductor memory device, particularly, a Dynamic Random Access Memory (DRAM) device, may typically include two regions, which include a first region and a second region. The first region may be a cell array in which memory cells are arranged in a matrix form, and the second region may be a peripheral circuit region for driving the cell array. The peripheral circuit region may include a non-repetitive circuit region that stores and transfers data and drives the cell array, and a repetitive circuit region including a sense amplifier, a decoder and the like. The repetitive circuit region may be referred to as a core region. For the sake of convenience, the peripheral circuit region including the core region may be referred to as a ‘peripheral region’.

Each of the peripheral regions may include an NMOS region and a PMOS region. Also, the peripheral region may be divided into a high-voltage transistor and a low-voltage transistor according to the voltage applied thereto. A high-voltage NMOS transistor and a low-voltage NMOS transistor may be formed in the NMOS region, and a high-voltage PMOS transistor and a low-voltage PMOS transistor may be formed in the PMOS region. For the reliability of the device, a gate dielectric layer applied to the high-voltage transistor may have a line width which is wider than the line width of the gate dielectric layer of the low-voltage transistor and may have a thickness Tox which is thicker than the thickness of the gate dielectric layer of the low-voltage transistor. The high-voltage transistor may be referred to as a ‘thick transistor’, and the low-voltage transistor may be referred to as a ‘slim transistor’. Here, “thick” or “slim” may refer to the thickness of the gate dielectric layer.

In a DRAM, the peripheral region may be a CMOSFET (Complementary Metal Oxide Silicon Field Effect Transistor) using a gate first process and form a gate stack including a high-k layer and a metal electrode. Also, for threshold voltage modulation of the CMOSFET, lanthanum oxide may be applied to an NMOS transistor, and a SiGe channel layer may be formed for a PMOS transistor. To be specific, lanthanum oxide or a SiGe channel layer may be formed for the low-voltage transistor in the NMOS region and the transistor in the PMOS region to lower the threshold voltage.

To improve the performance of the NMOS transistor, scaling an inversion-layer thickness (Tinv) may be required. Also, in order to scale the Tinv, it is required to achieve reliability improvement in terms of early failure (a phenomenon in which an oxide layer is broken down even at a low voltage) and Time-Dependent Dielectric Breakdown (TDDB) of the gate dielectric layer.

To mitigate the initial failure of the gate dielectric layer, it is important to address the vacancy that is responsible for its breakdown. Specifically, to prevent or mitigate the initial failure of the gate dielectric layer, the vacancy that is the cause of the breakdown may need to be removed. However, a significant challenge arises with the lanthanum (La) in the lanthanum oxide which is commonly applied to the high-voltage transistor and the low-voltage transistor in the NMOS region. During the subsequent annealing process the lanthanum is continuously diffused into the gate dielectric layer, extracting oxygen away from the silicon dioxide (SiO₂) and forms lanthanum oxide (LaO). This phenomenon may increase the vacancies in the gate dielectric layer compromising its reliability and stability.

Due to this problem, even though a high-k layer is applied to the high-voltage transistor in the NMOS region, a gate dielectric layer which is thicker than the gate dielectric layer applied to a typical stack of silicon oxynitride (SiON) and polysilicon may be applied. This may cause not only a decrease in the performance of the device but also a decrease in the reliability due to the initial failure problem occurring in the high-k layer.

In the case of DRAM, unlike logic circuits, the application of a relatively high voltage of at least approximately 3V is used to drive a cell transistor. This required the development of a gate dielectric layer that exhibits improved exceptional stability throughout the manufacturing process. Such stability is crucial to ensure reliable performance and durability of the DRAM devices under these high-voltage operating conditions.

Therefore, according to an embodiment of the present disclosure, a structure in which lanthanum oxide is selectively applied to the low-voltage transistor of the NMOS region and a fabrication method thereof will be described.

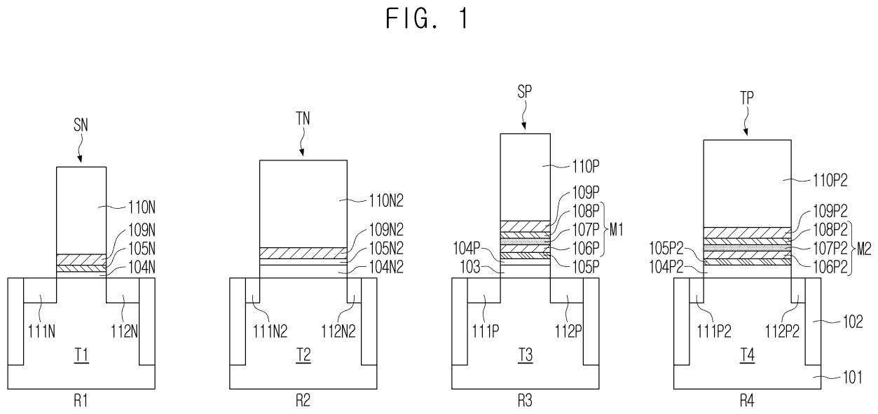

FIG. 1 is a cross-sectional view illustrating a semiconductor device in accordance with an embodiment of the present disclosure.

Referring to FIG. 1, the semiconductor device may include first to fourth transistors T1, T2, T3 and T4. The first to fourth transistors T1, T2, T3, T4 may be formed in a first, second, third, and fourth regions R1, R2, R3, and R4, respectively. The first to fourth transistors T1, T2, T3 and T4 may be isolated by an isolation layer 102. The first to fourth regions R1, R2, R3 and R4 may be isolated from each other by the isolation layer 102. The first to fourth transistors T1, T2, T3 and T4 may be a planar gate.

The first region R1 and the second region and R2 may be NMOS regions. The third region R3 and the fourth region R4 may be PMOS regions. The first gate stack SN and the second gate stack TN may be NMOS transistors. The third gate stack SP and the fourth gate stack TP may be PMOS transistors.

The line width of the first gate stack SN may be narrower than the line width of the second gate stack TN. The first gate stack SN may be referred to as a low-voltage NMOS transistor, and the second gate stack TN may be referred to as a high-voltage NMOS transistor. The line width of the third gate stack SP may be narrower than the line width of the fourth gate stack TP. The third gate stack SP may be referred to as a low-voltage PMOS transistor, and the fourth gate stack TP may be referred to as a high-voltage PMOS transistor.

The first transistor T1 may include a first gate stack SN, a first source region 111N, and a first drain region 112N. The first gate stack SN may be formed over substrate 101. The first source region 111N and the first drain region 112N may be formed in the substrate 101 on both sides of the first gate stack SN.

The first gate stack SN may include a first gate dielectric layer 104N, a first high-k layer 105N, a first metal electrode 109N, and a first hard mask layer 110N that are stacked in the mentioned order. The first high-k layer 105N may include a first dipole-inducing chemical species. To be specific, the first high-k layer 105N may include a first dipole interface at the interface with the first gate dielectric layer 104N. As will be described later, the first dipole-inducing chemical species may be diffused from the dielectric capping layer containing the first dipole-inducing chemical species to form a first dipole interface. The threshold voltage of the first transistor T1 may be modulated by the first dipole interface. The first dipole-inducing chemical species may include a lanthanum-based element. The first dipole-inducing chemical species may include lanthanum (La).

The second transistor T2 may include a second gate stack TN formed over the substrate 101, a second source region 111N2 and a second drain region 112N2. The second source region 111N2 and the second drain region 112N2 may be formed in the substrate 101 on both sides of the second gate stack TN.

The second gate stack TN may include a second gate dielectric layer 104N2, a second high-k layer 105N2, a second metal electrode 109N2, and a second hard mask layer 110N2 that are stacked in the mentioned order. The thickness of the second gate dielectric layer 104N2 may be thicker than the thickness of the first gate dielectric layer 104N.

The third transistor T3 may include a third gate stack SP formed over the substrate 101, a third source region 111P, and a third drain region 112P. The third source region 111P, and the third drain region 112P may be formed in the substrate 101 on both sides of the third gate stack SP.

The third gate stack SP may include a third gate dielectric layer 104P, a third high-k layer 105P, a first metal stack M1, a third metal electrode 109P, and a third hard mask layer 110P that are stacked in the mentioned order.

The third gate stack SP may further include a P-channel layer 103 formed over the substrate 101 and below the third gate stack SP. The P-channel layer 103 may be interposed between the third gate stack SP and the substrate 101. For example, the P-channel layer 103 may include silicon germanium (SiGe). The silicon germanium may include undoped silicon germanium. The P-channel layer 103 may be formed by an epitaxial process. The concentration of germanium in the P-channel layer 103 and the thickness of the P-channel layer 103 may be adjusted to the concentration and thickness optimized for reducing the threshold voltage Vt and improving the device characteristics. For example, the concentration of germanium in the P-channel layer 103 may range from approximately 10% to 40%, and the thickness may be adjusted to a thickness of approximately 70 Å to 90 Å, but the embodiments of the present disclosure are not limited thereto. According to another embodiment of the present disclosure, the concentration of germanium in the P-channel layer 103 and the thickness of the P-channel layer 103 may be further increased. The third high-k layer 105P may include a second dipole-inducing chemical species. To be specific, the third high-k layer 105P may include a second dipole interface at the interface with the third gate dielectric layer 104P. The second dipole-inducing chemical species may include an aluminum-based element. The second dipole-inducing chemical species may include aluminum (Al).

The fourth transistor T4 may include a fourth gate stack TP formed over the substrate 101, and a fourth source region 111P2 and a fourth drain region 112P2 that are formed in the substrate 101 on both sides of the fourth gate stack TP.

The fourth gate stack TP may include a fourth gate dielectric layer 104P2, a fourth high-k layer 105P2, a second metal stack M2, a fourth metal electrode 109P2, and a fourth hard mask layer 110P2 that are stacked in the mentioned order. The thickness of the fourth gate dielectric layer 104P2 may be thicker than the thickness of the third gate dielectric layer 104P. The fourth high-k layer 105P2 may include a second dipole-inducing chemical species. To be specific, the fourth high-k layer 105P2 may include a second dipole interface at the interface with the fourth gate dielectric layer 104P2. The second dipole-inducing chemical species may include an aluminum-based element. The second dipole-inducing chemical species may include aluminum (Al).

The first to fourth interface layers 104N, 104N2, 104P and 104P2 may be made of the same material. The first to fourth interface layers 104N, 104N2, 104P and 104P2 may be made of silicon oxide.

The first to fourth high-k layers 105N, 105N2, 105P and 105P2 may include high-k materials having high dielectric constants (high-k). The first to fourth high-k layers 105N, 105N2, 105P and 105P2 may have dielectric constants which are larger than the dielectric constant of silicon dioxide (SiO₂) (approximately 3.9). Also, the first to fourth high-k layers 105N, 105N2, 105P and 105P2 may be physically significantly thicker than silicon dioxide (SiO₂) and may have lower equivalent oxide thickness (EOT) values than silicon dioxide (SiO₂). The dielectric constants of the first to fourth high-k layers 105N, 105N2, 105P and 105P2 may be larger than those of the first to fourth interface layers 104N, 104N2, 104P and 104P2.

The first to fourth high-k layers 105N, 105N2, 105P and 105P2 may include metal-containing materials, such as metal oxides, metal silicates, and metal silicate nitrides. For example, the metal oxides may include oxides containing metals, such as hafnium (Hf), aluminum (Al), lanthanum (La), zirconium (Zr) and the like. For example, the metal oxides may include hafnium oxide, aluminum oxide, lanthanum oxide, zirconium oxide, or a combination thereof. For example, the metal oxides may include hafnium oxide (HfO₂O), aluminum oxide (Al₂O₃), lanthanum oxide (La₂O₃), or zirconium oxide (ZrO₂), or a combination thereof. The metal silicates may include silicates containing metals, such as hafnium (Hf), zirconium (Zr) and the like. For example, the metal silicate may include hafnium silicate (HfSiO), zirconium silicate (ZrSiO), or a combination thereof. The metal silicate nitride may include hafnium silicate nitride (HfSiON), zirconium silicate nitride (ZrSiON), or a combination thereof.

For example, the first high-k layer 105N may include hafnium silicate nitride (HfSiON) including lanthanum oxide (LaO) as a dipole interface. Also, the second high-k layer 105N2 may include hafnium silicate nitride (HfSiON) that does not include an impurity. Also, the third and fourth high-k layers 105P and 105P2 may include hafnium silicate nitride (HfSiON) including aluminum oxide (AlO) as a dipole interface. The embodiments of the present disclosure are not limited thereto, and the type of the dipole-inducing chemical species and the dielectric material may be replaced as needed.

The first and second metal stacks M1 and M2 may include the same stack formed of the same material. For example, the first and second metal stacks M1 and M2 may include a stacked structure of titanium nitride (TiN) including titanium nitride (TiN)/aluminum (Al)/lanthanum (La).

The first to fourth metal electrodes 109N, 109N2, 109P and 109P2 may be of the same material. For example, the first to fourth metal electrodes 109N, 109N2, 109P and 109P2 may include a metal nitride, such as titanium nitride.

The first to fourth hard mask layers 110N, 110N2, 110P and 110P2 may be of the same material. For example, the first to fourth hard mask layers 110N, 110N2, 110P and 110P2 may include silicon nitride.

As described above, according to this embodiment of the present disclosure, it is possible to prevent deterioration of the second gate dielectric layer 104N2 and the second high-k layer 105N2 due to the dipole-inducing chemical species by applying the first high-k layer 105N including a dipole interface only to the first gate stack SN that requires threshold voltage to be modulated, and applying the second high-k layer 105N2 that does not include a dipole interface or a dipole-inducing chemical species to the second gate stack TN. For the second gate stack (TN), applying the second high-k layer (105N2), which is designed without a dipole interface or dipole-inducing chemical species, ensures enhanced stability and performance.

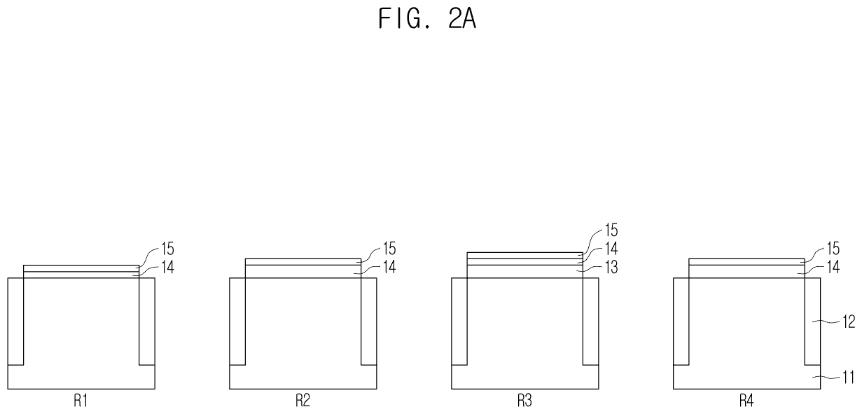

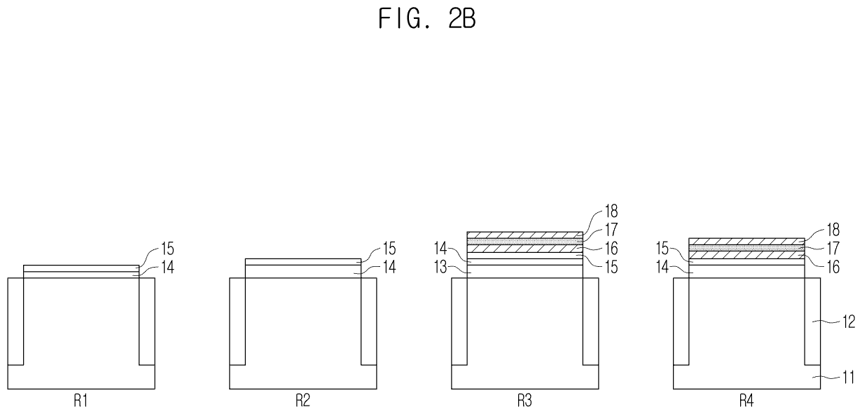

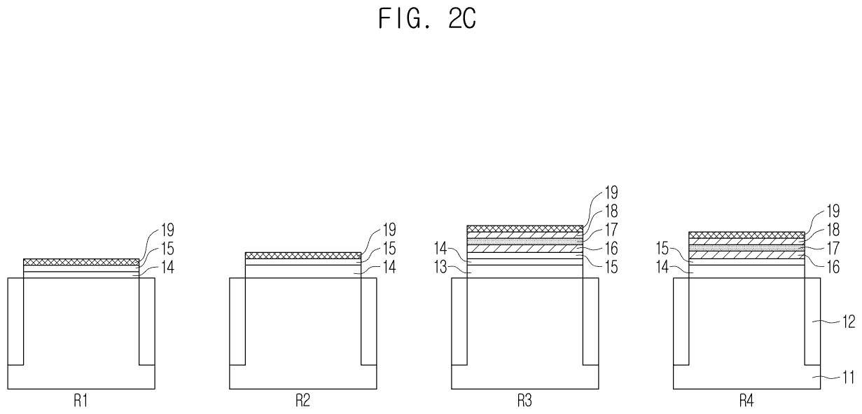

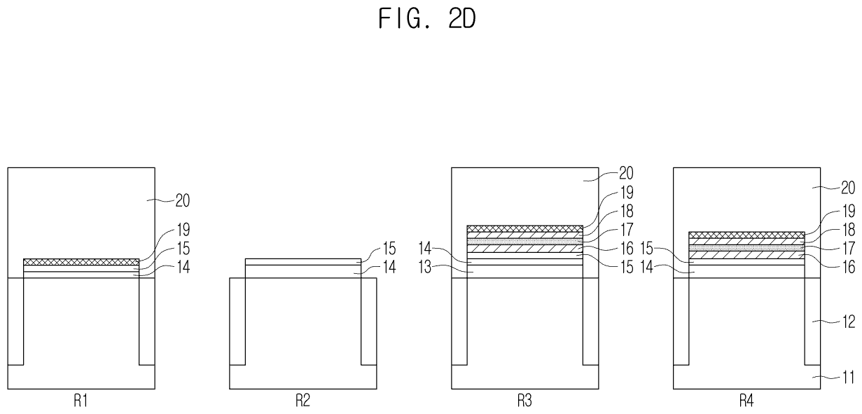

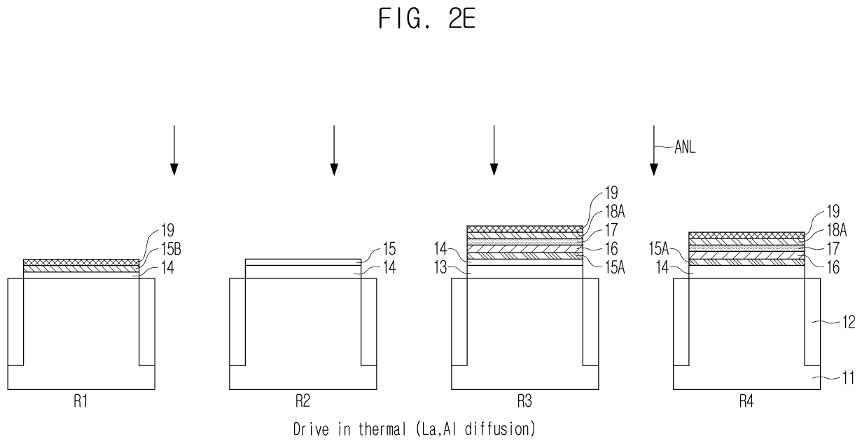

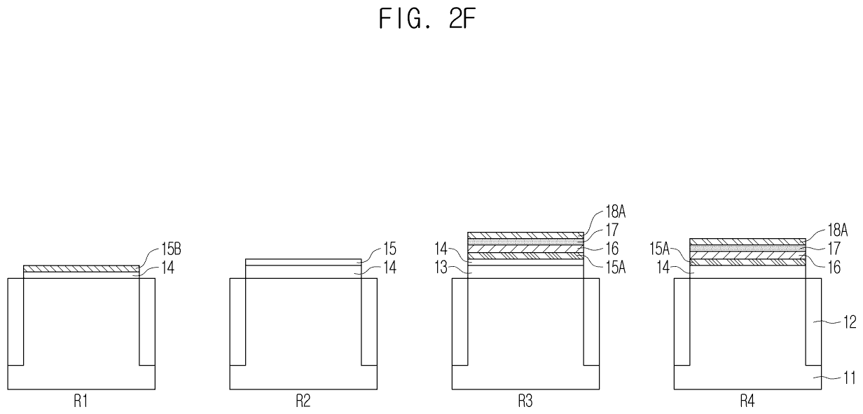

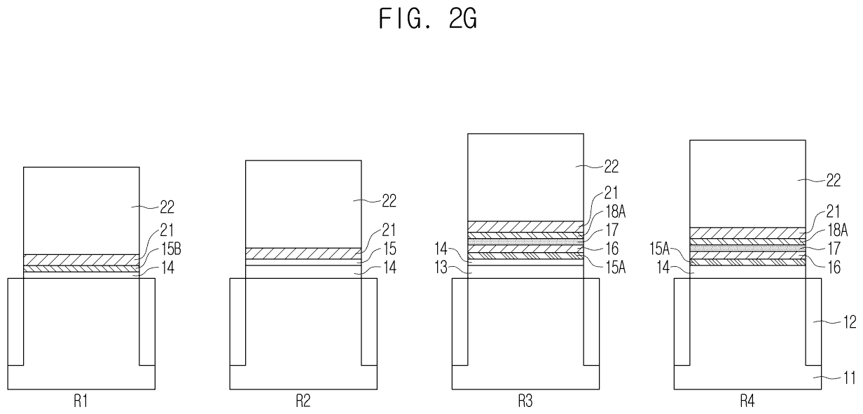

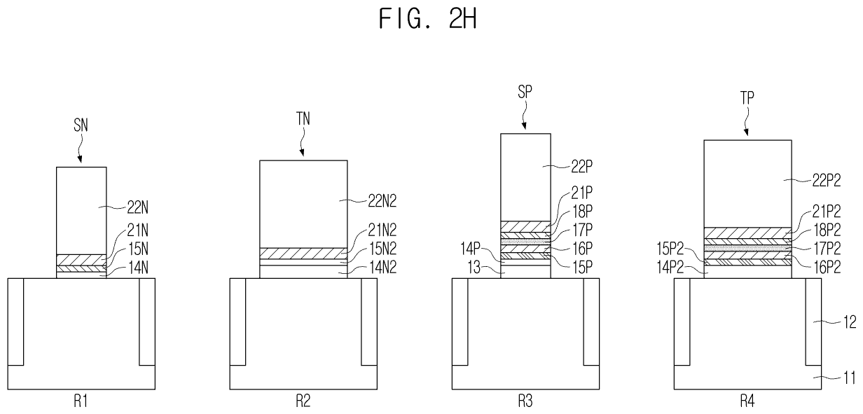

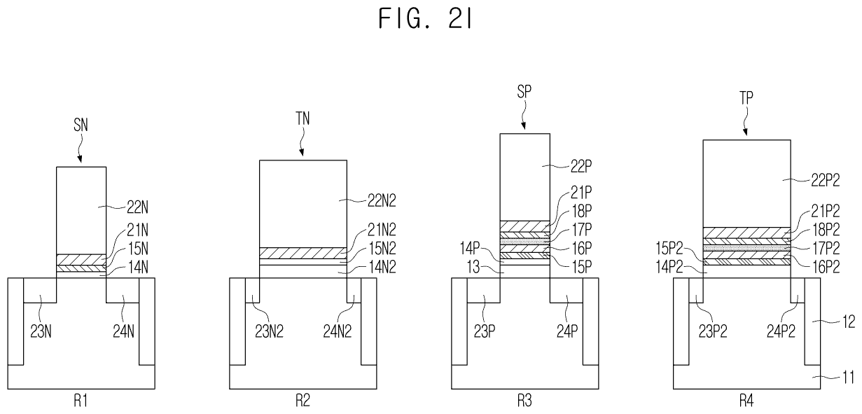

FIGS. 2A to 2I are process cross-sectional views illustrating a method for fabricating a semiconductor device in accordance with an embodiment of the present disclosure.

Referring to FIG. 2A, a substrate 11 may be prepared. The substrate 11 may include a plurality of regions where transistors are formed. The regions may include first to fourth regions R1 to R4. The substrate 11 may include a semiconductor material. The substrate 11 may include a semiconductor substrate. The substrate 11 may include a silicon substrate, a silicon germanium substrate, or a Silicon-On-Insulator (SOI) substrate.

An isolation layer 12 may be formed in the substrate 11. The isolation layer 12 may be formed through a Shallow Trench Isolation (STI) process.

The first to fourth regions R1 to R4 may be isolated from each other by the isolation layer 12. The first region R1 and the second region R2 may be the regions where NMOS transistors are to be formed. The first region R1 may be a region where a high-voltage NMOS transistor having a thin gate dielectric layer is to be formed. The second region R2 may be a region where a low-voltage NMOS transistor having a thick gate dielectric layer is to be formed. The third and fourth regions R3 and R4 may be the regions where PMOS transistors are to be formed. The third region R3 may be a region where a low-voltage PMOS transistor having a thin gate dielectric layer is to be formed. The fourth region R4 may be a region where a high-voltage PMOS transistor having a thick gate dielectric layer is to be formed. Although not illustrated, a well may be formed in the substrate 11 through a typical well forming process. A P-type well may be formed in the substrate 11 of the first and second regions R1 and R2, and an N-type well may be formed in the substrate 11 of the third and fourth regions R3 and R4.

Subsequently, a P-channel layer 13 may be selectively formed over the substrate 11 of the third region R3. The P-channel layer 13 may include silicon germanium (SiGe). The P-channel layer 13 may be crystalline. The P-channel layer 13 may be formed by a Selective Epitaxial Growth (SEG) process. The silicon germanium may include undoped silicon germanium. The concentration and thickness of germanium in the P-channel layer 13 may be adjusted to the concentration and thickness that are optimized for reducing the threshold voltage Vt and improving the device characteristics. For example, the concentration of germanium in the P-channel layer 13 may range from approximately 10% to 40%, and the thickness may be adjusted to a thickness of approximately 70 Å to 90 Å, but the embodiments of the present disclosure are not limited thereto. According to another embodiment of the present disclosure, the concentration and thickness of germanium in the P-channel layer 13 may be further increased.

Subsequently, a gate dielectric material 14 may be formed. The gate dielectric material 14 may be formed on the surface of the substrate 11 of the first, second, and fourth regions, R1, R2, and R4. The gate dielectric material 14 may be formed over the P-channel layer 13 of the third region R3. The gate dielectric material 14 may include an oxide-based material. The gate dielectric material 14 may include silicon oxide. For example, the silicon oxide may include silicon dioxide (SiO₂).

The thickness of the gate dielectric material 14 of the second region R2 and the fourth region R4 may be thicker than the thickness of the gate dielectric material 14 of the first region R1 and the third region R3.

Subsequently, a high-k material 15 may be formed over the gate dielectric material 14 of the first to fourth regions R1 to R4. The high-k material 15 may have a high dielectric constant (high-k). The high-k material 15 may have a dielectric constant which is larger than the dielectric constant of silicon oxide (SiO₂) (approximately 3.9). Also, the high-k material 15 may be physically thicker than silicon oxide (SiO₂) and may have an equivalent oxide thickness (EOT) value which is lower than that of silicon oxide (SiO₂). The high-k material 15 may have a dielectric constant which is larger than that of the gate dielectric material 14. The high-k material 15 may include a metal oxide, a metal silicate, a metal silicate nitride and the like. The metal oxide may include an oxide containing a metal, such as hafnium (Hf), aluminum (Al), lanthanum (La), zirconium (Zr) and the like. The metal oxide may include hafnium oxide, aluminum oxide, lanthanum oxide, zirconium oxide, or a combination thereof. For example, the metal oxide may include HfO₂, Al₂O₃, La₂O₃, ZrO₂, or a combination thereof. The metal silicate may include a silicate containing a metal, such as hafnium (Hf), zirconium (Zr) and the like. For example, the metal silicate may include hafnium silicate (HfSiO), zirconium silicate (ZrSiO), or a combination thereof. The metal silicate nitride may include hafnium silicate nitride (HfSiON), zirconium silicate nitride (ZrSiON), or a combination thereof. According to this embodiment of the present disclosure, the high-k material 15 may include HfSiO. The HfSiO may be formed by Atomic Layer Deposition (ALD).

Referring to FIG. 2B, first to third metal-containing layers 16, 17 and 18 may be formed over the high-k material 15 of the third region R3 and the fourth region R4.

The first metal-containing layer 16 may prevent the metal material in the second metal-containing layer 17 from being diffused into the NMOS region. The second metal-containing layer 17 may include a second dipole-inducing chemical species. The metal material in the second metal-containing layer 17 may be diffused into the interface between the high-k material 15 and the gate dielectric material 14 during a subsequent annealing process to form a second dipole interface. The third metal-containing layer 18 may serve as a barrier to prevent the first dipole-inducing chemical species in the subsequent dielectric capping layer from being diffused into the lower portion, i.e., the PMOS region.

The first and third metal-containing layers 16 and 18 may include the same material. The first and third metal-containing layers 16 and 18 may include a metal nitride. For example, the first and third metal-containing layers 16 and 18 may include titanium nitride (TiN). For example, the second metal-containing layer 17 may include aluminum (Al).

The first to third metal-containing layers 16, 17 and 18 may be formed through a series of processes of sequentially forming the first to third metal-containing layers 16, 17 and 18 over the high-k material 15 of the first to fourth regions R1 to R4, and then etching the first to third metal-containing layers 16, 17 and 18 of the first and second regions R1 and R2. Referring to FIG. 2C, a dielectric capping material 19 may be formed in the first to fourth regions R1 to R4. The dielectric capping material 19 of the first and second regions R1 and R2 may be formed over the high-k material 15. The dielectric capping material 19 of the third and fourth regions R3 and R4 may be formed over the third metal-containing layer 18.

The dielectric capping material 19 may contain a first dipole-inducing chemical species. The first dipole-inducing chemical species may be diffused into the interface between the high-k material 15 and the gate dielectric material 14 during a subsequent process, e.g., an annealing process. For example, the first dipole-inducing chemical species may include lanthanum. For example, the dielectric capping material 19 may include lanthanum oxide (LaO). The dielectric capping material 19 may be formed by Atomic Layer Deposition (ALD) or Physical Vapor Deposition (PVD).

Referring to FIG. 2D, a mask pattern 20 may be formed. The mask pattern 20 may include a photoresist. The mask pattern 20 may be formed in the first region R1, the third region R3, and the fourth region R4. The second region R2 may be exposed by the mask pattern 20. The dielectric capping material 19 of the second region R2 may be exposed by the mask pattern 20.

Subsequently, using the mask pattern, the dielectric capping material 19 of the second region R2 may be removed. The dielectric capping material 19 may remain in the first, third, and fourth regions R1, R3, and R4, and may be completely removed in the second region R2.

Subsequently, the mask pattern 20 may be removed.

After the mask pattern 20 is removed, a stack of the gate dielectric material 14, the high-k material 15, and the dielectric capping material 19 may remain in the first region R1. A stack of the gate dielectric material 14 and the high-k material 15 may remain in the second region R2. A stack of the P-channel layer 13, the gate dielectric material 14, the high-k material 15, the first to third metal-containing layers 16, 17 and 18, and the dielectric capping material 19 may remain in the third region R3. A stack of the gate dielectric material 14, the high-k material 15, the first to third metal-containing layers 16, 17 and 18, and the dielectric capping material 19 may remain in the fourth region R4.

Referring to FIG. 2E, an annealing process ANL may be performed.

During the annealing process ANL, The first dipole-inducing chemical species may be diffused from the dielectric capping material 19 into the interface between the high-k material 15 of the first region R1 and the gate dielectric material 14. The first dipole-inducing chemical species may also be diffused into the third metal-containing layer 18 of the third region R3 and the fourth region R4, but may not be diffused downward due to the barrier role of the third metal-containing layer 18. Therefore, the first dipole-inducing chemical species may not affect the material properties.

Also, in the third region R3 and the fourth region R4, a metal element, i.e., a second dipole-inducing chemical species, may be diffused from the second metal-containing layer 17 into the interface between the high-k material 15 of the third region R3 and the fourth region R4 and the gate dielectric material 14 through the first metal-containing layer 16 during the annealing process ANL. The metal element diffused from the second metal-containing layer 17 may serve as the second dipole-inducing chemical species. The second dipole-inducing chemical species may function to modulate the threshold voltage of the PMOS transistor. The second dipole-inducing chemical species, for example, aluminum (Al), may pass through the first metal-containing layer 16 because aluminum has a small particle size. Moreover, since aluminum (Al) has a strong tendency to react with oxygen, aluminum (Al) may be diffused into an area with a lot of oxygen, that is, into the interface between the high-k material 15 and the gate dielectric material 14. As a comparative example, in contrast to the embodiment of the present disclosure, when a metal-containing layer is formed first in the first region R1 and the second region R2 before forming the dielectric capping layer 19, the first dipole-inducing chemical species in the dielectric capping layer 19 may not pass through the metal-containing layer. Therefore, the first dipole-inducing chemical species may not be diffused into the interface between the high-k material 15 and the gate dielectric material 14, preventing the formation of a dipole interface.

Nitrogen may be implanted into the high-k material 15 of the first and second regions R1 and R2 during the annealing process ANL. For example, as the high-k material 15, hafnium silicon oxide (HfSiO) may be modified into hafnium silicon oxynitride (HfSiON) by the annealing process ANL.

According to another embodiment of the present disclosure, plasma nitridation may be performed in advance onto the high-k material 15 of the first and second regions R1 and R2 before the annealing process ANL.

As described, during the annealing process ANL, both the first and second dipole-inducing chemical species are diffused into the high-k material 15, and the high-k material 15 may be nitridated at the same time. Referring to FIG. 2F, the dielectric capping material (19, see FIG. 2E) may be removed, for example, by using a wet etching process. For example, the wet etching process may include the use of HCl. The dielectric capping material 19 may be removed from all of the first to fourth regions R1 to R4.

Therefore, it is possible to prevent the problem that the residual lanthanum which is not diffused into the dielectric capping material 19 is diffused in the subsequent process and deteriorates the reliability of the transistor. Thus, it becomes feasible to address the issue of residual lanthanum that remains undiffused into the dielectric capping material 19. By preventing its diffusion during subsequent processes, the reliability of the transistor is preserved, ensuring stable performance and minimizing degradation.

Referring to FIG. 2G, a fourth metal-containing layer 21 may be formed. The fourth metal-containing layer 21 may include a metal or a metal nitride. For example, the fourth metal-containing layer 21 may include titanium nitride.

Subsequently, a hard mask layer 22 may be formed over the fourth metal-containing layer 21. For example, the hard mask layer 22 may include silicon nitride.

Referring to FIG. 2H, a gate patterning process may be performed. Using the unillustrated gate mask, first to fourth gate stacks SN, TN, SP and TP may be formed in the region R1 to R4, respectively.

The first gate stack SN may be formed in the first region R1, the second gate stack TN may be formed in the second region R2, the third gate stack SP may be formed in the third region R3, and the fourth gate stack SP may be formed in the fourth region R4.

The first gate stack SN may include a first gate dielectric layer 14N, a first high-k layer 15N, a first metal electrode 21N, and a first hard mask layer 22N that are stacked in the mentioned order.

The second gate stack TN may include a second gate dielectric layer 14N2, a second high-k layer 15N2, a second metal electrode 21N2, and a second hard mask layer 22N2 that are stacked in the mentioned order. The thickness of the second gate dielectric layer 14N2 may be thicker than the thickness of the first gate dielectric layer 14N. The first high-k layer 15N may include a first dipole-inducing chemical species.

The third gate stack SP may include a third gate dielectric layer 14P, a third high-k layer 15P, a first metal stack M1 (16P,17P,18P), a third metal electrode 21P, and a third hard mask layer 22P that are stacked in the mentioned order. The third high-k layer 15P may include a second dipole-inducing chemical species.

The fourth gate stack TP may include a fourth gate dielectric layer 14P2, a fourth high-k layer 15P2, a second metal stack M2 (16P2,17P2, 18P2), a fourth metal electrode 21P2, and a fourth hard mask layer 22P2 that are stacked in the mentioned order. The thickness of the fourth gate dielectric layer 14P2 may be thicker than the thickness of the third gate dielectric layer 14P. The fourth high-k layer 15P2 may include a second dipole-inducing chemical species.

The first to fourth metal electrodes 21N, 21N2, 21P and 21P2 may be of the same material and may have the same thickness. The first to fourth hard mask layers 22N, 22N2, 22P and 22P2 may be of the same material and may have the same thickness.

Referring to FIG. 2I, a source/drain forming process and the like may be performed. A first source/drain region 23N/24N may be formed in the first region R1, and a second source/drain region 23N2/24N2 may be formed in the second region R2. A third source/drain region 23P/24P may be formed in the third region R3, and a fourth source/drain region 23P2/24P2 may be formed in the fourth region R4.

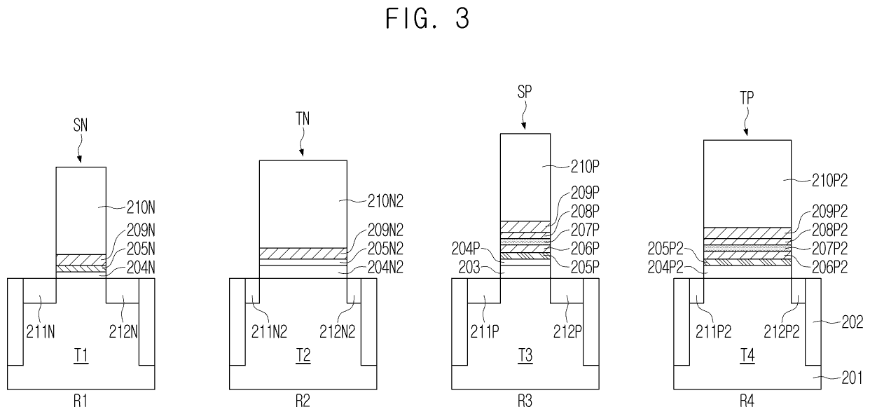

FIG. 3 is a cross-sectional view illustrating a semiconductor device in accordance with another embodiment of the present disclosure. FIG. 3 may be the same as or similar to FIG. 1, except for the gate stack structures SP and TP of the third region and the fourth region.

Referring to FIG. 3, the semiconductor device may include first to fourth transistors T1, T2, T3 and T4, formed in the first to fourth regions, R1, R2, R3, and R4 respectively. Specifically, the first transistor T1 may be formed in the first region R1, the second transistor T2 may be formed in the second region R2, the third transistor T3 may be formed in the third region R3, and the fourth transistor T4 may be formed in the fourth region R4. The first to fourth transistors T1, T2, T3 and T4 may be isolated by an isolation layer 202. The first to fourth regions R1, R2, R3 and R4 may be isolated from each other by the isolation layer 202.

The first and second regions R1 and R2 may be NMOS regions, and the third and fourth regions R3 and R4 may be PMOS regions. The first gate stack SN and the second gate stack TN may be NMOS transistors, and the third gate stack SP and the fourth gate stack TP may be PMOS transistors.

The line width of the first gate stack SN may be narrower than the line width of the second gate stack TN. The first gate stack SN may be referred to as a low-voltage NMOS transistor, and the second gate stack TN may be referred to as a high-voltage NMOS transistor. The line width of the third gate stack SP may be narrower than the line width of the fourth gate stack TP. The third gate stack SP may be referred to as a low-voltage PMOS transistor, and the fourth gate stack TP may be referred to as a high-voltage PMOS transistor.

The first transistor T1 may include a first gate stack SN formed over a substrate 201, and a first source region 211N and a first drain region 212N that are formed over the substrate 201 on both sides of the first gate stack SN.

The first gate stack SN may include a first gate dielectric layer 204N, a first high-k layer 205N, a first metal electrode 209N, and a first hard mask layer 210N that are stacked in the mentioned order. The first high-k layer 205N may include a first dipole-inducing chemical species. To be specific, the first high-k layer 205N may include a first dipole interface at the interface with the first gate dielectric layer 204N. As will be described later, a first dipole interface may be formed as the dipole-inducing chemical species is diffused from a dielectric capping layer containing the first dipole-inducing chemical species. The threshold voltage of the first transistor T1 may be modulated by the first dipole interface. The first dipole-inducing chemical species may include a lanthanum-based element. The first dipole-inducing chemical species may include lanthanum (La).

The second transistor T2 may include a second gate stack TN formed over the substrate 201, and a second source region 211N2 and a second drain region 212N2 that are formed over the substrate 201 on both sides of the second gate stack TN.

The second gate stack TN may include a second gate dielectric layer 204N2, a second high-k layer 205N2, a second metal electrode 209N2, and a second hard mask layer 210N2 that are stacked in the mentioned order. The thickness of the second gate dielectric layer 204N2 may be thicker than the thickness of the first gate dielectric layer 204N.

The third transistor T3 may include a third gate stack SP formed over the substrate 201, and a third source region 211P and a third drain region 212P that are formed over the substrate 201 on both sides of the third gate stack SP.

The third gate stack SP may include a third gate dielectric layer 204P, a third high-k layer 205P, a first metal stack M1 (206P, 207P, and 208P), a third metal electrode 209P, and a third hard mask layer 210P that are stacked in the mentioned order. The third gate stack SP may further include a P-channel layer 203 formed over the substrate 201 and below the third gate stack SP. The P-channel layer 203 may be interposed between the third gate stack SP and the substrate 201. For example, the P-channel layer 103 may include silicon germanium (SiGe). The silicon germanium may include undoped silicon germanium. The P-channel layer 103 may be formed by an epitaxial process. The concentration and thickness of germanium in the P-channel layer 103 may be adjusted to the concentration and thickness optimized for reducing the threshold voltage Vt and improving the device characteristics. For example, the concentration of germanium in the P-channel layer 103 may range from approximately 10% to 40%, and the thickness may be adjusted to a thickness of approximately 70 Å to 90 Å, but the embodiments of the present disclosure are not limited thereto. According to another embodiment of the present disclosure, the concentration and thickness of germanium in the P-channel layer 103 may be further increased. The third high-k layer 205P may include a second dipole-inducing chemical species. To be specific, the third high-k layer 205P may include a second dipole interface at the interface with the third gate dielectric layer 204P. The second dipole-inducing chemical species may include an aluminum-based element. The second dipole-inducing chemical species may include aluminum (Al).

The fourth transistor T4 may include a fourth gate stack TP formed over the substrate 201. A fourth source region 211P2 and a fourth drain region 212P2 of the fourth transistor may be formed over the substrate 201 on both sides of the fourth gate stack TP.

The fourth gate stack TP may include a fourth gate dielectric layer 204P2, a fourth high-k layer 205P2, a second metal stack M2, a fourth metal electrode 209P2, and a fourth hard mask layer 210P2 that are stacked in the mentioned order. The thickness of the fourth gate dielectric layer 204P2 may be thicker than the thickness of the third gate dielectric layer 204P. The fourth high-k layer 205P2 may include a second dipole-inducing chemical species. To be specific, the fourth high-k layer 205P2 may include a second dipole interface at the interface with the fourth gate dielectric layer 204P2. The second dipole-inducing chemical species may include an aluminum-based element. The second dipole-inducing chemical species may include aluminum (Al).

The first to fourth interface layers 204N, 204N2, 204P and 204P2 may be of the same material. The first to fourth interface layers 204N, 204N2, 204P and 204P2 may be silicon oxide.

The first to fourth high-k layers 205N, 205N2, 205P and 205P2 may include high-k materials having high dielectric constants (high-k). The first to fourth high-k layers 205N, 205N2, 205P and 205P2 may have dielectric constants that are larger than the dielectric constant of silicon dioxide (SiO₂) (approximately 3.9). Also, the first to fourth high-k layers 205N, 205N2, 205P and 205P2 may be physically considerably thicker than silicon dioxide (SiO₂) and have equivalent oxide thickness (EOT) values that are lower than that of silicon dioxide (SiO₂). The first to fourth high-k layers 205N, 205N2, 205P and 205P2 may have dielectric constants that are larger than those of the first to fourth interface layers 204N, 204N2, 204P and 204P2.

The first to fourth high-k layers 205N, 205N2, 205P and 205P2 may include a metal-containing material, such as a metal oxide, a metal silicate, a metal silicate nitride and the like. For example, the metal oxide may include an oxide containing a metal, such as hafnium (Hf), aluminum (Al), lanthanum (La), zirconium (Zr) and the like. For example, the metal oxide may include hafnium oxide, aluminum oxide, lanthanum oxide, zirconium oxide, or a combination thereof. For example, the metal oxide may include HfO₂, Al₂O₃, La₂O₃, ZrO₂, or a combination thereof. The metal silicate may include a silicate containing a metal, such as hafnium (Hf), zirconium (Zr) and the like. For example, the metal silicate may include hafnium silicate (HfSiO), zirconium silicate (ZrSiO), or a combination thereof. The metal silicate nitride may include hafnium silicate nitride (HfSiON), zirconium silicate nitride (ZrSiON), or a combination thereof.

For example, the first high-k layer 205N may include hafnium silicate nitride (HfSiON) containing lanthanum oxide (LaO) as a dipole interface. Also, the second high-k layer 205N2 may include hafnium silicate nitride (HfSiON) that does not include an impurity. Also, the third and fourth high-k layers 205P and 205P2 may include hafnium silicate nitride (HfSiON) containing aluminum oxide (AlO) as a dipole interface. The embodiments of the present disclosure are not limited thereto, and the type of the dipole-inducing chemical species and the high-dielectric material may be replaced as needed.

The first and second metal stacks M1 and M2 may include the same stack formed of the same material. For example, the first and second metal stacks M1 and M2 may include a stacked structure of titanium nitride (TiN)/aluminum (Al)/titanium nitride (TiN).

The first to fourth metal electrodes 209N, 209N2, 209P and 209P2 may be of the same material. For example, the first to fourth metal electrodes 209N, 209N2, 209P and 209P2 may include a metal nitride, such as titanium nitride.

The first to fourth hard mask layers 210N, 210N2, 210P and 210P2 may be of the same material and, may include, for example, silicon nitride.

As described above, according to this embodiment of the present disclosure, it is possible to prevent the deterioration of the second gate dielectric layer 204N2 and the second high-k layer 205N2 due to the dipole-inducing chemical species by applying the first high-k layer 205N including the dipole interface only to the first gate stack SN that requires a threshold voltage to be modulated, and applying the second high-k layer 205N2 that does not include a dipole interface or a dipole-inducing chemical species to the second gate stack TN.

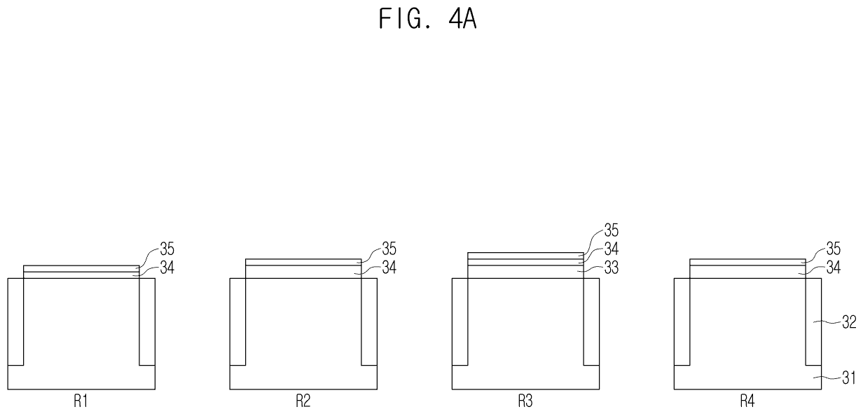

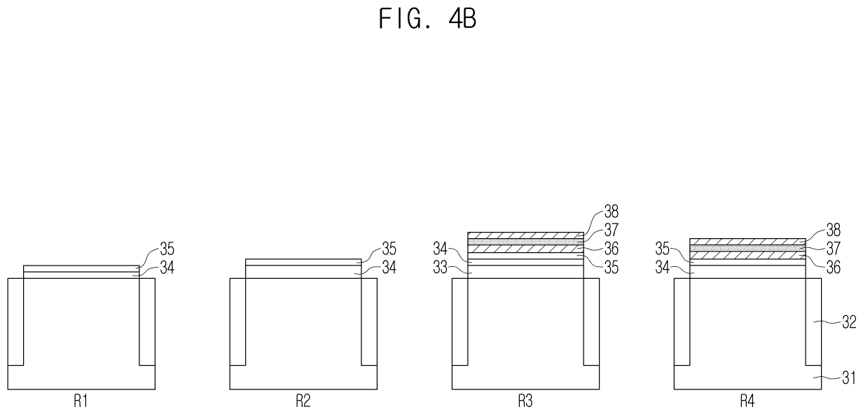

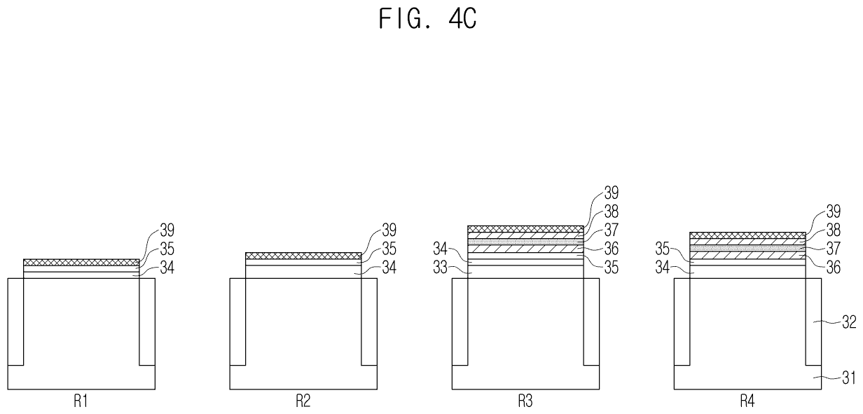

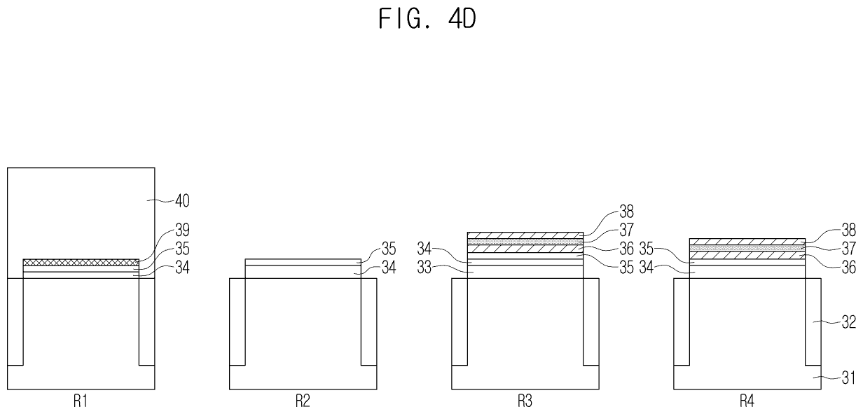

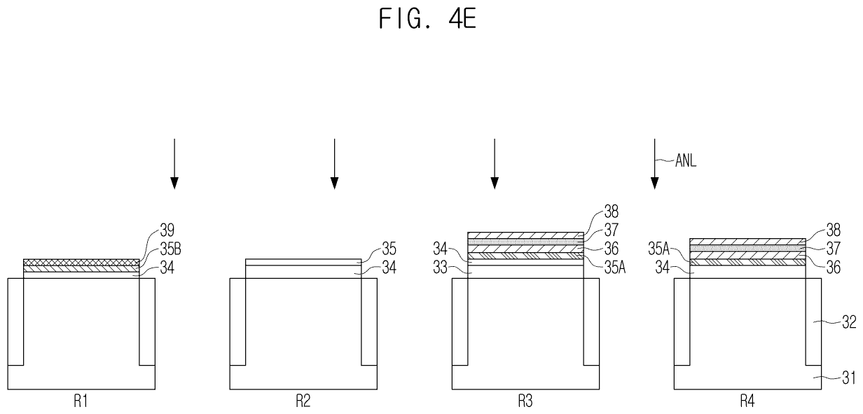

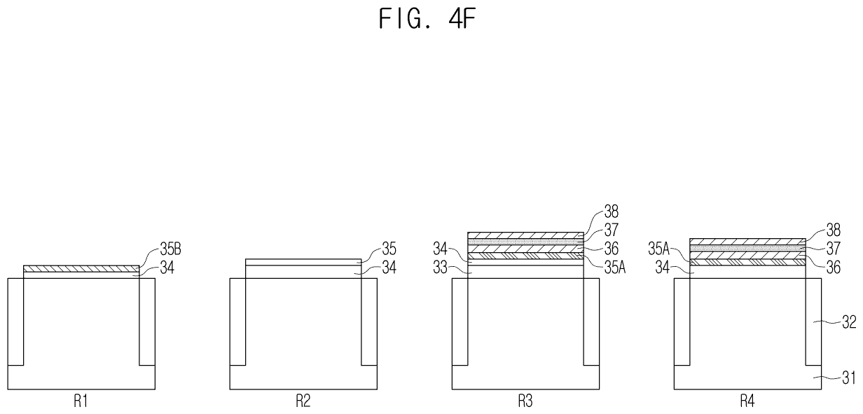

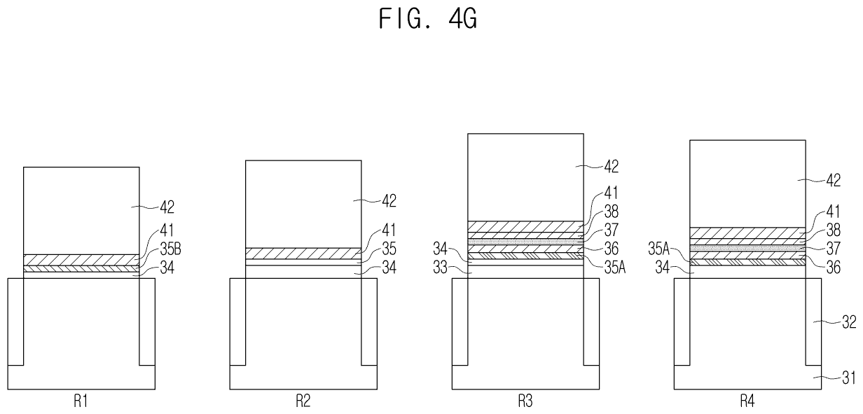

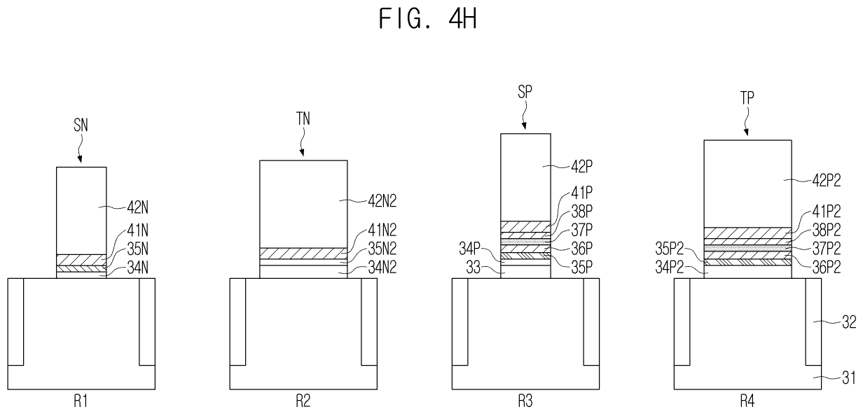

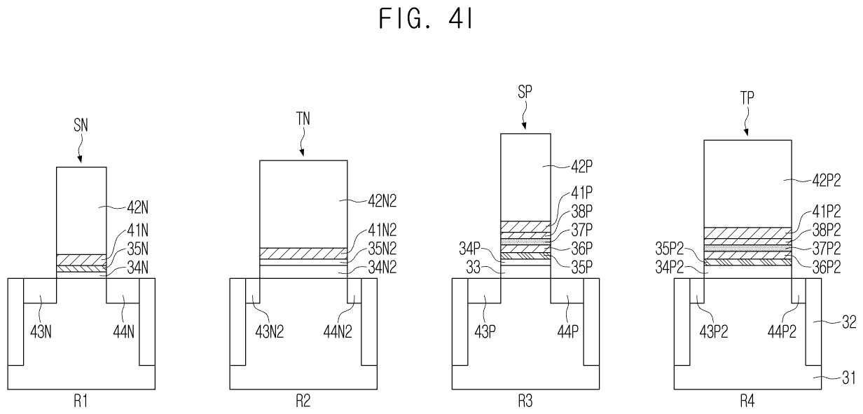

FIGS. 4A to 4I are process cross-sectional views illustrating a method for fabricating a semiconductor device in accordance with another embodiment of the present disclosure.

Referring to FIG. 4A, a substrate 31 may be prepared. The substrate 31 may include a plurality of regions in which transistors are formed. The regions may include first to fourth regions R1 to R4. The substrate 31 may include a semiconductor material. The substrate 31 may include a semiconductor substrate. The substrate 31 may include a silicon substrate, a silicon germanium substrate, or a Silicon-On-Insulator (SOI) substrate.

An isolation layer 32 may be formed in the substrate 31. The isolation layer 32 may be formed through a Shallow Trench Isolation (STI) process.

The first to fourth regions R1 to R4 may be isolated from each other by the isolation layer 32. The first and second regions R1 and R2 may be the regions where NMOS transistors are to be formed. The first region R1 may be a region where a high-voltage NMOS transistor having a thin gate dielectric layer is to be formed, and the second region R2 may be a region where a low-voltage NMOS transistor having a thick gate dielectric layer is to be formed. The third and fourth regions R3 and R4 may be the regions where PMOS transistors are to be formed. The third region R3 may be a region where a low-voltage PMOS transistor having a thin gate dielectric layer is to be formed, and the fourth region R4 may be a region where a high-voltage PMOS transistor having a thick gate dielectric layer is to be formed. Although not illustrated, a well may be formed in the substrate 31 through a typical well forming process. A P-type well may be formed in the substrate 31 of the first and second regions R1 and R2, and an N-type well may be formed in the substrate 31 of the third and fourth regions R3 R4.

Subsequently, a P-channel layer 33 may be selectively formed over the substrate 31 of the third region R3. The P-channel layer 33 may include silicon germanium (SiGe). The P-channel layer 33 may be formed by a Selective Epitaxial Growth (SEG) process. The silicon germanium may include undoped silicon germanium. The concentration and thickness of germanium in the P-channel layer 33 may be adjusted to the concentration and thickness optimized for reducing the threshold voltage Vt and improving the device characteristics. For example, the concentration of germanium in the P-channel layer 33 may range from approximately 10% to 40%, and the thickness may be adjusted to a thickness of approximately 70 Å to 90 Å, but the embodiments of the present disclosure are not limited thereto. According to another embodiment of the present disclosure, the concentration and thickness of germanium in the P-channel layer 33 may be further increased.

Subsequently, a gate dielectric material 34 may be formed. The gate dielectric material 34 may be formed on the surface of the substrate 31 of the first, second, and fourth regions, R1, R2, and R4. The gate dielectric material 34 may be formed over the P-channel layer 33 of the third region R3. The gate dielectric material 34 may include an oxide-based material. The gate dielectric material 34 may include silicon oxide. For example, the silicon oxide may include silicon dioxide (SiO₂).

The thickness of the gate dielectric material 34 of the second and fourth regions R2 and R4 may be thicker than the thickness of the gate dielectric material 34 of the first and third regions R1 and R3.

Subsequently, a high-k material 35 may be formed over the gate dielectric material 34 of the first to fourth regions R1 to R4. The high-k material 35 may have a high dielectric constant (high-k). The high-k material 35 may have a dielectric constant which is larger than the dielectric constant of silicon oxide (SiO₂) (approximately 3.9). Also, the high-k material 35 may be physically thicker than silicon oxide (SiO₂) and may have an equivalent oxide thickness (EOT) value which is lower than that of silicon oxide (SiO₂). The high-k material 35 may have a dielectric constant which is larger than that of the gate dielectric material 34. The high-k material 35 may include a metal oxide, a metal silicate, a metal silicate nitride, and the like. The metal oxide may include an oxide containing a metal, such as hafnium (Hf), aluminum (Al), lanthanum (La), zirconium (Zr) and the like. The metal oxide may include hafnium oxide, aluminum oxide, lanthanum oxide, zirconium oxide, or a combination thereof. For example, the metal oxide may include HfO₂, Al₂O₃, La₂O₃, ZrO₂, or a combination thereof. The metal silicate may include a silicate containing a metal, such as hafnium (Hf), zirconium (Zr) and the like. For example, the metal silicate may include hafnium silicate (HfSiO), zirconium silicate (ZrSiO), or a combination thereof. The metal silicate nitride may include hafnium silicate nitride (HfSiON), zirconium silicate nitride (ZrSiON), or a combination thereof. According to this embodiment of the present disclosure, the high-k material 35 may include HfSiO, and the HfSiO may be formed by an Atomic Layer Deposition (ALD) process.

Referring to FIG. 4B, the first to third metal-containing layers 36, 37 and 38 may be formed over the high-k material 35 of the third and fourth regions R3 and R4. The first and third metal-containing layers 36 and 38 may include the same material. The first and third metal-containing layers 36 and 38 may include a metal nitride, for example, titanium nitride (TiN). For example, the second metal-containing layer 37 may include aluminum (Al).

The first to third metal-containing layers 36, 37 and 38 may be formed through a series of processes of sequentially forming the first to third metal-containing layers 36, 37 and 38 over the high-k material 35 of the first to fourth regions R1 to R4, and then etching the first to third metal-containing layers 36, 37 and 38 of the first and second regions R1 and R2.

Referring to FIG. 4C, a dielectric capping material 39 may be formed in the first to fourth regions R1 to R4. The dielectric capping material 39 of the first and second regions R1 and R2 may be formed over the high-k material 35. The dielectric capping material 39 of the third and fourth regions R3 and R4 may be formed over the third metal-containing layer 38. The dielectric capping material 39 may contain a first dipole-inducing chemical species. The first dipole-inducing chemical species may be diffused into the interface between the high-k material 35 and the gate dielectric layer 34 from a subsequent process. The dielectric capping material 39 may include lanthanum. The dielectric capping material 39 may include lanthanum oxide (LaO). For example, the dielectric capping material 39 may be formed by Atomic Layer Deposition (ALD) or Physical Vapor Deposition (PVD).

Referring to FIG. 4D, a mask pattern 40 may be formed only in the first region R1, and expose the second region R2, the third region R3 and the fourth region R4. The mask pattern 40 may include a photoresist. The dielectric capping material 39 of the second region R2, the third region R3 and the fourth region R4 may be exposed by the mask pattern 40.

Subsequently, the exposed dielectric capping material 39 of the second region R2, the third region R3, and the fourth region R4 may be removed by using the mask pattern 40. The dielectric capping material 39 may remain in the first region R1, and the second region R2, the third region R3 and the fourth region R4 may all be removed.

Subsequently, the mask pattern 40 may be removed. After the mask pattern 40 is removed, a stack of the gate dielectric material 34, the high-k material 35, and the dielectric capping material 39 may remain in the first region R1. A stack of the gate dielectric material 34 and the high-k material 35 may remain in the second region R2. A stack of the P-channel layer 33, the gate dielectric material 34, the high-k material 35, and the first to third metal-containing layers 36, 37 and 38 may remain in the third region R3. A stack of the gate dielectric material 34, the high-k material 35, and the first to third metal-containing layers 36, 37 and 38 may remain in the fourth region R4.

Referring to FIG. 4E, an annealing process ANL may be performed. The first dipole-inducing chemical species may be diffused from the dielectric capping material 39 by the annealing process ANL. The first dipole-inducing chemical species may be diffused into the interface between the high-k material 35 of the first region R1 and the gate dielectric layer 34.

At the same time, in the third region R3 and the fourth region R4, the metal element from the second metal-containing layer 37 may pass through the first metal-containing layer 36 to be diffused into the interface between the high-k material 35 of the third region R3 and the fourth region R4 and the gate dielectric layer 34 during the annealing process ANL. The metal element diffused from the second metal-containing layer 17 may serve as the second dipole-inducing chemical species. The second dipole-inducing chemical species may function to modulate the threshold voltage of the PMOS transistor. For example, the second dipole-inducing chemical species may include aluminum. The second dipole-inducing chemical species, for example, aluminum (Al), may have particles which are so small that they may pass through the first metal-containing layer 36. Furthermore, aluminum (Al) may have a strong tendency to react with oxygen, and thus aluminum (Al) may be diffused into an area with a lot of oxygen, that is, into the interface between the high-k material 35 and the gate dielectric layer 34. Nitrogen may be implanted into the high-k material 35 of the first and second regions R1 and R2 during the annealing process ANL. For example, hafnium silicon oxide (HfSiO) as the high-k material 35 may be modified into hafnium silicon oxynitride (HfSiON) by the annealing process ANL.

According to another embodiment of the present disclosure, plasma nitridation may be performed in advance onto the high-k material 35 of the first and second regions R1 and R2 before the annealing process ANL is performed.

As described above, the high-k material 35 may be nitridated simultaneously while the first and second dipole-inducing chemical species are diffused into the high-k material 35 during the annealing process ANL.

Referring to FIG. 4F, the dielectric capping material (39, see FIG. 4E) may be removed, for example, by a wet etching process. In an embodiment, the wet etching process may be performed by using HCl.

Therefore, it is possible to prevent the problem that the residual lanthanum which is not diffused into the dielectric capping material 39 is diffused in the subsequent process and deteriorates the reliability of the transistor. Thus, the issue of residual lanthanum that remains undiffused into the dielectric capping material 39 can be effectively addressed. By preventing its diffusion during subsequent processes, the transistor's reliability can be safeguarded, ensuring stable operation and mitigating potential degradation.

Referring to FIG. 4G, a fourth metal-containing layer 41 may be formed in all first to fourth regions R1 to R4. The fourth metal-containing layer 41 may include a metal or a metal nitride. For example, the fourth metal-containing layer 41 may include titanium nitride.

Subsequently, a hard mask layer 42 may be formed over the fourth metal-containing layer 41 in all first to fourth regions R1 to R4. For example, the hard mask layer 42 may include silicon nitride.

Referring to FIG. 4H, gate patterning may be performed. Using an unillustrated gate mask, first to fourth gate stacks SN, TN, SP and TP may be formed in the regions R1 to R4.

The first gate stack SN may be formed in the first region R1, the second gate stack TN may be formed in the second region R2, the third gate stack SP may be formed in the third region R3, and the fourth gate stack SP may be formed in the fourth region R4.

The first gate stack SN may include a first gate dielectric layer 34N, a first high-k layer 35N, a first metal electrode 41N, and a first hard mask layer 42N that are stacked in the mentioned order.

The second gate stack TN may include a second gate dielectric layer 34N2, a second high-k layer 35N2, a second metal electrode 41N2, and a second hard mask layer 42N2 that are stacked in the mentioned order. The thickness of the second gate dielectric layer 34N2 may be thicker than the thickness of the first gate dielectric layer 34N. The first high-k layer 35N may include a first dipole-inducing chemical species.

The third gate stack SP may include a third gate dielectric layer 34P, a third high-k layer 35P, a first metal stack M1, a third metal electrode 41P, and a third hard mask layer 42P that are stacked in the mentioned order. The third high-k layer 35P may include a second dipole-inducing chemical species.

The fourth gate stack TP may include a fourth gate dielectric layer 34P2, a fourth high-k layer 35P2, a second metal stack M2, a fourth metal electrode 41P2, and a fourth hard mask layer 42P2 that are stacked in the mentioned order. The thickness of the fourth gate dielectric layer 34P2 may be thicker than the thickness of the third gate dielectric layer 34P. The fourth high-k layer 35P2 may include a second dipole-inducing chemical species.

The first to fourth metal electrodes 41N, 41N2, 41P and 41P2 may be of the same material and may also have the same thickness. The first to fourth hard mask layers 42N, 42N2, 42P and 42P2 may be of the same material and may also have the same thickness.

Referring to FIG. 4I, a source/drain forming process and the like may be performed. A first source/drain region 43N/44N may be formed in the first region R1, and a second source/drain region 43N2/44N2 may be formed in the second region R2. A third source/drain region 43P/44P may be formed in the third region R3, and a fourth source/drain region 43P2/44P2 may be formed in the fourth region R4.

According to the embodiment of the present disclosure, it is possible to prevent the gate dielectric layer from being broken down by applying a gate structure that is optimized for each peripheral region.

Also, according to the embodiment of the present disclosure, it is possible to improve the reliability and performance of a semiconductor device.

While the embodiments of the present disclosure have been described with respect to the specific embodiments, it will be apparent to those skilled in the art that various changes and modifications may be made without departing from the context and scope of the present disclosure. Furthermore, the embodiments may be combined to form additional embodiments.

What is claimed is:

1. A semiconductor device comprising:
a substrate including a first NMOS region and a second NMOS region whose line width is different from a line width of the first NMOS region;
a first conductive pattern including a stacked structure of a first gate dielectric layer and a first metal electrode positioned in an upper portion of the substrate of the first NMOS region, and including a first high-k layer interposed at an interface between the first gate dielectric layer and the first metal electrode and containing a dipole-inducing chemical species; and
a second conductive pattern including a stacked structure of a second gate dielectric layer and a second metal electrode positioned in an upper portion of the substrate of the second NMOS region, and including a second high-k layer interposed at an interface between the second gate dielectric layer and the second metal electrode.

2. The semiconductor device of claim 1, wherein the line width of the second NMOS region is larger than the line width of the first NMOS region, and
a thickness of the second gate dielectric layer is thicker than a thickness of the first gate dielectric layer.

3. The semiconductor device of claim 1, wherein the dipole-inducing chemical species contains a lanthanum-based material.

4. The semiconductor device of claim 1, wherein the dipole-inducing chemical species forms a dipole interface at an interface between the first high-k layer and the first gate dielectric layer.

5. The semiconductor device of claim 1, wherein the first and second gate dielectric layers include silicon oxide.

6. The semiconductor device of claim 1, wherein the first and second metal electrodes include titanium nitride.

7. The semiconductor device of claim 1, wherein the first and second high-k layers include hafnium silicon oxynitride.

8. The semiconductor device of claim 1, wherein the first and second conductive patterns include a planar gate.

9. A semiconductor device comprising:
a substrate including a first NMOS region, a second NMOS region whose line width is different from a line width of the first NMOS region, a first PMOS region, and a second PMOS region whose line width is different from a line width of the first PMOS region;
a first conductive pattern including a stacked structure of a first gate dielectric layer and a first metal electrode in the upper portion of the substrate of the first NMOS region, and including a first high-k layer interposed at an interface between the first gate dielectric layer and the first metal electrode and containing a first dipole-inducing chemical species;
a second conductive pattern including a stacked structure of a second gate dielectric layer and a second metal electrode in the upper portion of the substrate of the second NMOS region, and including a second high-k layer interposed at an interface between the second gate dielectric layer and the second metal electrode;
a third conductive pattern including a stacked structure of a third gate dielectric layer and a third metal electrode in the upper portion of the substrate of the first PMOS region, and including a third high-k layer interposed at an interface between the third gate dielectric layer and the third metal electrode and containing a second dipole-inducing chemical species; and
a fourth conductive pattern including a stacked structure of a fourth gate dielectric layer and a fourth metal electrode in the upper portion of the substrate of the second PMOS region, and including a fourth high-k layer interposed at an interface between the fourth gate dielectric layer and the fourth metal electrode and containing the second dipole-inducing chemical species.

10. The semiconductor device of claim 9, wherein the line width of the second NMOS region is wider than the line width of the first NMOS region, and
a thickness of the second gate dielectric layer is thicker than a thickness of the first gate dielectric layer.

11. The semiconductor device of claim 9, wherein the line width of the second PMOS region is wider than the line width of the first PMOS region, and
a thickness of the fourth gate dielectric layer is thicker than a thickness of the third gate dielectric layer.

12. The semiconductor device of claim 9, wherein the first dipole-inducing chemical species contains a lanthanum-based material.

13. The semiconductor device of claim 9, wherein the first dipole-inducing chemical species forms a first dipole interface at an interface between the first high-k layer and the first gate dielectric layer.

14. The semiconductor device of claim 9, wherein the second dipole-inducing chemical species contains an aluminum-based material.

15. The semiconductor device of claim 9, wherein the second dipole-inducing chemical species forms a second dipole interface at an interface between the third high-k layer and the fourth high-k layer and the third gate dielectric layer and the fourth gate dielectric layer.

16. The semiconductor device of claim 9, wherein the third conductive pattern further includes a first metal stack between the third high-k layer and the third metal electrode, and
the fourth conductive pattern further includes a second metal stack between the fourth high-k layer and the fourth metal electrode.

17. The semiconductor device of claim 16, wherein each of the first and second metal stacks includes a stack of a first titanium nitride, aluminum, and a second titanium nitride.

18. The semiconductor device of claim 9, wherein the first to fourth high-k layers include hafnium silicon oxynitride.

19. The semiconductor device of claim 9, wherein the first to fourth conductive patterns include planar gates.

20. The semiconductor device of claim 9, further comprising:
a P-channel layer at an interface between the substrate of the first PMOS region and the third gate dielectric layer.

21. The semiconductor device of claim 20, wherein the P-channel layer includes silicon germanium.
